(19) United States
(12) Patent Application Publication
(10) Pub. No.: US 2018/0182546 A1
(43) Pub. Date: Jun. 28, 2018

(54) CAPACITOR UNIT AND ELECTRICAL APPARATUS

(71) Applicant: GENERAL ELECTRIC TECHNOLOGY GMBH, Schenectady, NY (US)

(72) Inventors: John Lewis OUTRAM, Stone, Staffordshire (GB); Stephen David BUTLER, Essington, South Staffordshire (GB)

(21) Appl. No.: 15/739,257

(22) PCT Filed: May 6, 2016
(86) PCT No.: PCT/EP2016/060229

§ 371 Date: Dec. 22, 2017

(30) Foreign Application Priority Data
Jun. 29, 2015 (GB) 1511331.9

(51) Int. Cl. H01G 2/10; H05K 5/06; H05K 5/02; H05K 5/04; H01G 2/02; H02B 1/20; H02B 1/21

(52) U.S. Cl. CPC H01G 2/103; H05K 5/06; H05K 5/0247; H01L 23/3675; H01G 2/02; H02B 1/205; H02B 1/21; H05K 5/04

(57) ABSTRACT

There is provided a capacitor unit, for use as a high voltage device, comprising: a capacitor element; a housing (including a plurality of walls arranged to contain the capacitor element within the housing, the plurality of walls including first and second end walls, the plurality of walls further including a side wall extending between the end walls, the outer surface of the side wall being larger than the outer surface of each end wall; and at least one capacitor terminal electrically connected to the capacitor element, wherein the or each capacitor terminal is mounted on or extends through the side wall.

### FIELD OF INVENTION

This invention relates to a capacitor unit, for use as a high voltage device, and an electrical apparatus, for use as a high voltage electrical apparatus.

### BACKGROUND OF THE INVENTION

It is known to use a capacitor for a range of electrical applications, such as power electrical modules.

### SUMMARY OF INVENTION

According to a first aspect of the invention, there is provided a capacitor unit, for use as a high voltage device, comprising: a capacitor element; a housing including a plurality of walls arranged to contain the capacitor element within the housing, the plurality of walls including first and second end walls, the plurality of walls further including a side wall extending between the end walls, the outer surface of the side wall being larger than the outer surface of each end wall; and at least one capacitor terminal electrically connected to the capacitor element, wherein the or each capacitor terminal is mounted on or extends through the side wall.

The location of the or each capacitor terminal at the side wall of the capacitor unit of the invention not only ensures excellent usage of space and at the same time provides ready access to the or each capacitor terminal during the use of the capacitor unit in a range of activities, such as manufacture, repair, maintenance, etc, but also can reduce the mechanical/thermal stresses and tolerances imposed on an electrical apparatus that combines the capacitor unit with another electrical component. This in turn allows for a more flexible and more cost-efficient design of the capacitor unit of the invention and the corresponding electrical apparatus, thus permitting reductions in the design complexity and cost of the associated high voltage applications.

In contrast, in a conventional capacitor unit, its capacitor terminals are located at one of the end walls. Thus, in order to maximise usage of space when the capacitor unit is combined with another electrical component, it is necessary to accommodate the location of the capacitor terminals at the end wall by adding a bend to the part of the other electrical component that electrically engages the capacitor terminals. The requirement of the bent portion in the other electrical component not only restricts access to the capacitor terminals of the conventional capacitor unit but also introduces additional mechanical/thermal stresses and tolerances to the corresponding electrical apparatus, thus applying limitations to the design of the conventional capacitor unit and the corresponding electrical apparatus comprising such a conventional capacitor unit. Such design limitations further complicate the use of the conventional capacitor unit as a high voltage device, since there are already numerous other design requirements that need to be taken into consideration in order to meet performance and safety conditions associated with high voltage applications.

There are a number of ways in which the capacitor unit can be designed to be suitable for use as a high voltage device, examples of which are described as follows:

The capacitor unit may be rated for use in a high voltage direct current (HVDC) application or a static VAR compensator (SVC) application.

The capacitor unit may have a voltage rating of more than 1500 V DC.

The housing may be metallic.

The housing may be hermetically sealed.

The capacitor unit may include a or a respective bushing arranged around the or each capacitor terminal. The provision of the or each bushing in the capacitor unit helps to maintain any existing hermetic seal, insulate the or each capacitor terminal from the housing, and provide electrical creepage distance between the or each capacitor terminal and the housing.

According to a further aspect of the invention, there is provided a use of a capacitor unit as a high voltage device, wherein the capacitor unit is in accordance with any one of the embodiments of the first aspect of the invention. In such use of the capacitor unit, the high voltage device may be a high voltage direct current device or a static VAR compensator device.

In embodiments of the invention, a recess may be formed in the side wall, and the or each capacitor terminal may be mounted on or may extend through a base of the recess. In such embodiments, the height of the or each capacitor terminal above the base of the recess may be equal to or less than the depth of the recess. In other such embodiments, the height of the or each capacitor terminal above the base of the recess may be greater than the depth of the recess.

The location of the or each capacitor terminal in the recess formed in the side wall limits the extent to which the or each capacitor terminal extends away from the side-wall, thus resulting in a more space-efficient capacitor unit.

Optionally the recess may be formed as an end recess adjacent to one of the end walls. The location of the or each capacitor terminal in the end recess provides ready access to the or each capacitor terminal when combining the capacitor unit with another electrical component.

In further embodiments of the invention the or each capacitor terminal may extend perpendicularly or substantially perpendicularly to the outer surface of the side wall. The arrangement of the or each capacitor terminal in this manner permits ready connection of the or each capacitor terminal to another electrical component.

In still further embodiments of the invention the or each capacitor terminal may be positioned adjacent to a wall edge that joins the side wall and one of the end walls. The arrangement of the or each capacitor terminal in this manner also permits ready connection of the or each capacitor terminal to another electrical component.

It will be appreciated that the capacitor unit of the invention may include a single capacitor element or a plurality of capacitor elements.

According to a second aspect of the invention, there is provided an electrical apparatus comprising: the capacitor unit of the invention described herein; and another electrical component including: a component terminal that electrically and releasably engages with the capacitor terminal; or a plurality of component terminals, each of which electrically and releasably engages with a respective one of the capacitor terminals.

The or each component terminal may include a slot in which the corresponding capacitor terminal is releasably engaged. This improves the integrity of the electrical engagement between the capacitor and component terminals, thus enhancing the reliability of the electrical apparatus.

The or each component terminal may slidably engage with the corresponding capacitor terminal. When the or each component terminal includes a slot, the or each capacitor terminal may be slidably engaged in the slot of the corresponding component terminal.

The provision of a sliding engagement between the capacitor and component terminals permits the use of a sliding motion to engage and disengage the capacitor and component terminals, thus reducing the amount of space required to assemble and disassemble the electrical apparatus.

The capacitor unit and the other electrical component may be mounted on a support rail so that: the capacitor unit is slidable along the support rail relative to the other electrical component; and/or the other electrical component is slidable along the support rail relative to the capacitor unit. This provides a reliable means of providing slidable engagement between the capacitor and component terminals.

The other electrical component may be positioned to be coplanar or substantially coplanar with the capacitor unit. This coplanar arrangement simplifies the arrangement of the capacitor unit and the other electrical component in order to permit the engagement between the capacitor and component terminals.

It will be appreciated that the capacitor unit may be used in a range of electrical applications, and so the other electrical component may vary depending on the nature of the electrical application. For example, the other electrical component may be or may include a bus bar, optionally a laminated bus bar.

When the other electrical component is or includes a bus bar, the use of a sliding motion to engage and disengage the capacitor terminals and component terminals permits the bus bar, or the other electrical component including the bus bar, to be easily exchanged.

The or each component terminal may electrically and releasably engage with the or the respective capacitor terminal via mechanical contact. In such embodiments, the or each component terminal may electrically and releasably engage with the or the respective capacitor terminal solely via mechanical contact.

The use of mechanical contact to engage the component and capacitor terminals allows for reassembly and disassembly to aid maintenance and repair, which is not possible via permanent means of engaging the component and capacitor terminals, such as soldering.

There are a number of ways in which the electrical apparatus can be designed to be suitable for use as a high voltage electrical apparatus, examples of which are described as follows:

The electrical apparatus may be a voltage source converter (VSC).

The electrical apparatus may be rated for use in a HVDC application or an SVC application.

According to a still further aspect of the invention, there is provided a use of an electrical apparatus as a high voltage electrical apparatus, wherein the electrical apparatus is in accordance with any one of the embodiments of the second aspect of the invention. In such use of the electrical apparatus, the high voltage electrical apparatus may be a high voltage direct current electrical apparatus or a static VAR compensator electrical apparatus.

### BRIEF DESCRIPTION OF THE DRAWINGS

Embodiments of the invention will now be described, by way of non-limiting examples, with reference to the accompanying drawings in which:

FIG. 1 shows an electrical apparatus;

FIG. 2 shows a circuit diagram of an exemplary power electronic module; and

FIG. 3 shows an electrical apparatus; and

FIG. 4 shows a conventional electrical apparatus.

### DETAILED DESCRIPTION OF THE INVENTION

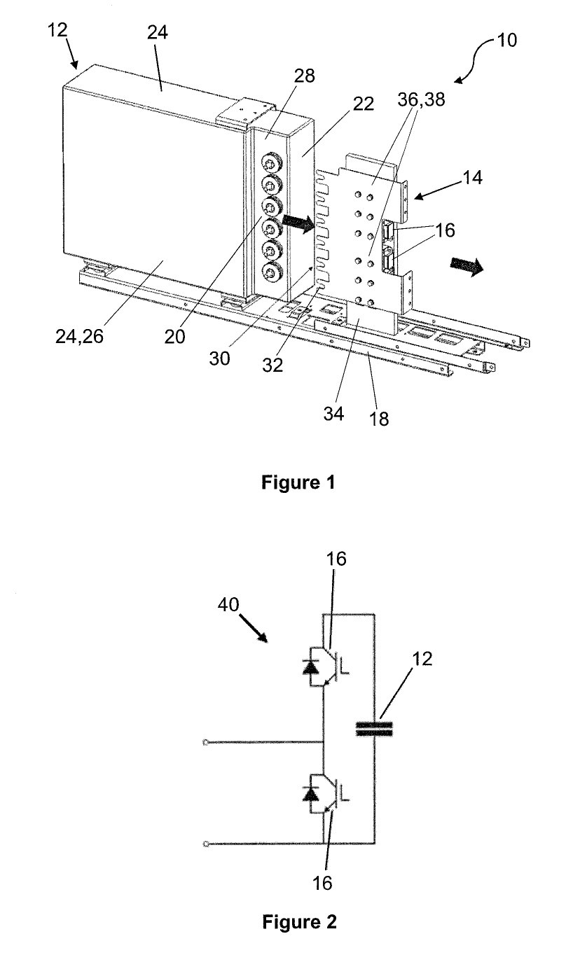

An electrical apparatus according to a first embodiment of in an embodiment shown in FIG. 1 and is designated generally by the reference numeral 10.

The electrical apparatus 10 is in the form of a power electronic module that comprises a capacitor unit 12, a laminated bus bar 14, a plurality of IGBTs 16 and a support rail 18.

In this embodiment, the power electronic module forms part of a voltage source converter (VSC) that is rated for use in a HVDC application or a SVC application. It will be appreciated that the electrical apparatus 10 may take the form of another type of high voltage electrical apparatus, in an embodiment rated for use in a high voltage direct current application or a static VAR compensator application.

The capacitor unit 12 is a high voltage device that includes a plurality of capacitor elements, a housing, and a plurality of capacitor terminals 20. The capacitor unit has a voltage rating of more than 1500 kV DC, and is thereby rated for use in a HVDC application or an SVC application.

The plurality of capacitor elements are connected to form multiple, electrically isolated capacitors, whereby each capacitor consists of one or more of the capacitor elements. It will be appreciated that each capacitor consisting of several capacitor elements may be formed from several series-connected capacitor elements, several parallel-connected capacitor elements, or a combination of several series-connected capacitor elements and several parallel-connected capacitor elements.

In the embodiment shown, each capacitor is connected to a respective pair of the plurality of capacitor terminals 20. The number of capacitor terminals 20 may vary depending on the number of capacitors in the capacitor unit 12.

In other embodiments of the invention, the capacitor unit may include a single capacitor element to form a single capacitor, or the plurality of capacitor elements may be connected to form a single capacitor. A single capacitor may connect to multiple pairs of capacitor terminals depending on the current rating of the capacitor terminals and the current rating of the capacitor.

In still other embodiments of the invention, a given capacitor may be arranged to be connected to a single capacitor terminal. In such embodiments, the housing may be used as an “earth return” terminal for the given capacitor.

The housing includes a plurality of walls arranged to contain the capacitor elements within the housing. The plurality of walls includes first and second end walls 22 and a plurality of additional walls 24. Each additional wall 24 extends between the first and second end walls 22 to form the housing. One of the additional walls 24 is formed as a side wall 24,26 dimensioned to have an outer surface that is larger than the outer surface of each end wall 22. The remaining additional walls 24 are dimensioned accordingly such that the shape of the housing resembles a plate structure. One of the additional walls 24, which is not the side wall 24,26, is attached to the support rail 18 so as to mount the capacitor unit 12 on the support rail 18. The housing is also formed as a metallic and hermetically sealed housing.

Each capacitor terminal 20 is in the form of a metal threaded stud that extends through a base of an end recess 28 formed in the side wall 24,26 and adjacent to one of the end walls 22. The height of each capacitor terminal 20 above the base of the end recess 28 is less than the depth of the end recess 28, but may be greater than or equal to the depth of the end recess 28 in other embodiments. The position of each capacitor terminal 20 is adjacent to a wall edge that joins the side wall 24,26 and the corresponding end wall, and the capacitor terminals 20 are arranged to form a row of capacitor terminals 20 parallel to the wall edge.

Each capacitor terminal 20 is electrically connected to the capacitor element(s) of the corresponding capacitor to provide electrical access to each capacitor element from the exterior of the capacitor unit 12. Each capacitor terminal 20 extends perpendicularly to the outer surface of the side wall 24,26, but in other embodiments may be modified to extend substantially perpendicularly to the outer surface of the side wall 24,26. A respective bushing is located about each capacitor terminal 20 to insulate the capacitor terminals 20 from the housing. Each bushing also helps to maintain the hermetic seal of the housing, and provide electrical creepage distance between the corresponding capacitor terminal 20 and the housing.

The laminated bus bar 14 is formed as a flat metal multi-layered sheet in which a plurality of component terminals 30 and a plurality of fastener openings 36 are formed. The plurality of component terminals 30 are in the form of a row of terminal tabs 30 spaced apart so that each terminal tab 30 is aligned with a respective one of the capacitor terminals 20. Each terminal tab 30 includes an open slot 32 into which the respective capacitor terminal 20 may be slid so as to be releasably engaged.

The plurality of IGBTs 16 are mounted on a cold plate 34, which in turn is mounted on the support rail 18 to position the IGBTs 16 to be substantially coplanar with the capacitor unit 12. Each fastener opening 36 of the laminated bus bar 14 are aligned with a respective one of the junction terminals of the IGBTs 16. A plurality of screw fasteners 38 are employed to fasten the laminated bus bar 14 to the junction terminals of the IGBTs 16 by way of each screw fastener 38 passing through a respective fastener opening 36 and screwed into a respective junction terminal.

The laminated bus bar 14 is designed such that each terminal tab 30 is electrically connected to one or more of the junction terminals of the IGBTs 16 when the laminated bus bar 14 is fastened to the IGBTs 16. The design of the electrical connections between the terminal tabs 30 and the junction terminals of the IGBTs 16 may vary depending on the switching requirements of the power electronic module 10.

Engaging the terminal tabs 30 and capacitor terminals 20 results in an electrical connection between each capacitor terminal 20 and one or more of the junction terminals of the IGBTs 16, thus electrically connecting the capacitors to the IGBTs 16. FIG. 2 shows a circuit diagram 40 of an exemplary power electronic module 10 that could be formed through the electrical connection between the capacitor terminals 20 and junction terminals. In use, the power electronic module 10 forms part of an electrical circuit in a voltage source converter for HVDC and SVC applications, and the IGBTs 16 may be switched to selectively insert the capacitors into the electrical circuit or form a current path that bypasses the capacitors, that is to say the IGBTs 16 may be switched to operate the power electronic module 10 to selectively provide a voltage source.

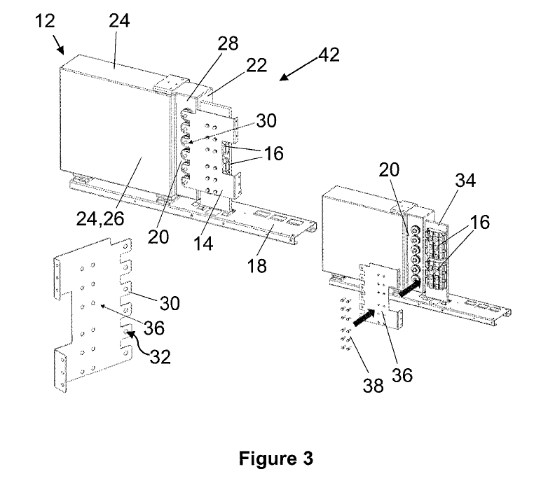

An electrical apparatus according to a second embodiment of shown in FIG. 3 and is designated generally by the reference numeral 42. The electrical apparatus 42 of FIG. 3 is similar in structure and operation to the electrical apparatus 10 of FIG. 1, and like features share the same reference numerals.

The electrical apparatus 42 of FIG. 3 differs from the electrical apparatus 10 of FIG. 1 in that, in the electrical apparatus 42 of FIG. 3, the slot 32 of each terminal tab 30 is formed as a closed slot instead of an open slot. In this manner each terminal tab 30 includes a closed slot 32 in which the respective capacitor terminal 20 may be inserted so as to be releasably engaged.

The arrangement of the various electrical components in the embodiments 10,42 of FIGS. 1 and 3 enables the capacitor unit 12, laminated bus bar 14 and IGBTs 16 to be substantially coplanar, thus resulting in a space-efficient power electronic module that in turn minimises the size of the electrical circuit of which the power electronic forms a part.

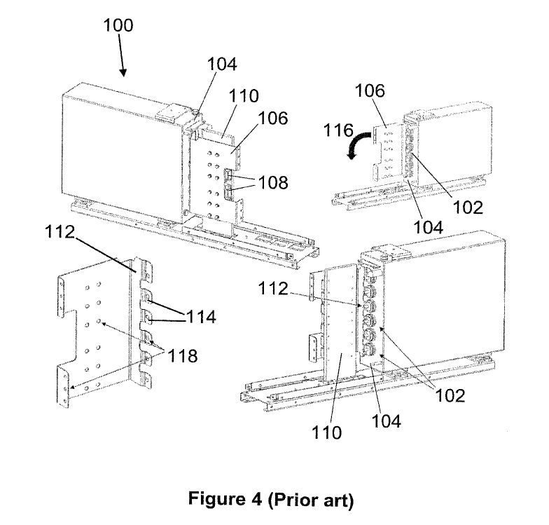

FIG. 4 shows a conventional electrical apparatus 100 in the form of a power electronic module based on a conventional capacitor unit. In the conventional capacitor unit, the capacitor terminals 102 extend through one of the end walls 104 such that each capacitor terminal 102 extends perpendicularly away from the outer surface of the end wall 104. This means that, in order to be able to arrange the conventional capacitor unit, laminated bus bar 106 and IGBTs 108 (as mounted on a cold plate 110) to be substantially coplanar so as to maximise the space usage efficiency of the power electronic module 100, part of the laminated bus bar 106 is bent to form a bent portion 112 so that the terminal tabs 114 are at a 90 degree angle relative to the rest of the laminated bus bar 106. By bending the laminated bus bar 106 in this manner, the terminal tabs 114 can engage the capacitor terminals 102 without preventing the substantially coplanar arrangement of the conventional capacitor unit, laminated bus bar 106 and IGBTs 108.

The arrangement of the various electrical components of the conventional power electronic module 100, however, results in restricted access to the capacitor terminals 102, thus causing space limitations that forces the assembly of the power electronic module 100 to follow a rigid assembly sequence. In the assembly sequence for the conventional power electronic module 100, the laminated bus bar 106 has to be first attached to the conventional capacitor unit by way of engagement between the terminal tabs 114 and capacitor terminals 102, prior to the fastening of the laminated bus bar 106 to the IGBTs 108. In addition the restricted access to the capacitor terminals 102 also results in the need for a rigid disassembly sequence when disassembling the power electronic module 100 for repair and maintenance.

Moreover the above assembly and disassembly sequences for the power electronic module 100 results in the cantilevered suspension of the laminated bus bar 106 off the capacitor terminals 102, which not only results in the application of mechanical stresses to the capacitor terminals 102 but also could comprise the accuracy of the position of the laminated bus bar 104 due to its suspended mass 116.

Furthermore the inclusion of a bent portion 112 in the laminated bus bar 104 for engagement with the capacitor terminals 102 not only contributes to the stresses imposed on the capacitor terminals 102 and the junction terminals of the IGBTs 108 as a result of an increase in tolerance stack (especially between the different holes 118 in the laminated bus bar 104), thermal movement and manufacturing alignment, which leads to increased manufacturing costs and the risk of decreased manufacturing accuracy.

The configuration of the electrical apparatus, embodiments 10,42 of which are shown in FIGS. 1 and 3, addresses the aforementioned problems associated with the conventional power electronic module.

In FIG. 1, the assembly sequence for the power electronic module 10 includes fastening the laminated bus bar 14 to the IGBTs 16 before using a sliding motion to engage the capacitor terminals 20 and terminal tabs 30. The disassembly sequence for the power electronic module 10 of FIG. 1 is the reverse of the assembly sequence, where disengaging the capacitor terminals 20 and terminal tabs 30 may require a slackening action depending on the level of fit between the capacitor terminals 20 and terminal tabs 30. The use of a sliding motion reduces the amount of space required to assemble and disassemble the power electronic module 10 since there would be no need for any lateral movement of the components during the assembly and disassembly steps, the direction of the lateral movement being perpendicular to the outer surface of the side wall 24,26. In addition the ability to engage or disengage the capacitor terminals 20 and terminal tabs 30 in a sliding motion facilitates a speedy assembly or disassembly of the power electronic module 10.

Furthermore the use of a sliding motion to engage and disengage the capacitor terminals 20 and terminal tabs 30 permits the power electronic module 10, in particular its parts that is not the capacitor unit 12 (such as the laminated bus bar 14 and the IGBTs 16), to be easily exchanged.

In FIG. 3, the assembly sequence for the power electronic module 42 includes mounting the capacitor unit 12 and cold plate 34 in their desired positions on the support rail 18 before placing the laminated bus bar 14 over the capacitor unit 12 and IGBTs 16 to allow engagement between the capacitor terminals 20 and terminal tabs 30 and to fasten the laminated bus bar 14 to the IGBTs 16. The disassembly sequence for the power electronic module 42 of FIG. 3 is the reverse of the assembly sequence. Whilst the assembly and disassembly sequences for the power electronic module 42 of FIG. 3 includes lateral movement of the components during the assembly and disassembly step, in an embodiment, the space requirements for the power electronic module 42 may be such that the lateral movement of the components is preferred over the relative sliding movement between the capacitor unit 12 and cold plate 34. Similarly the assembly and disassembly sequences for the power electronic module 42 of FIG. 3 facilitates a speedy assembly or disassembly of the power electronic module 42.

It can therefore be seen from the embodiments of FIGS. 1 and 3 that the location of the capacitor terminals 20 at the side wall 24,26 of the capacitor unit 12 provides improved access to the capacitor terminals 20 and thereby permits the use of different assembly and disassembly sequences, which can be selected to suit the space requirements of the electrical circuit of which the power electronic module 10,42 forms a part. Also, the time spent on the associated manufacturing, repair and maintenance activities is greatly reduced by the speedy nature of the assembly or disassembly of the power electronic module 10,42.

Furthermore the assembly and disassembly sequences of the power electronic modules 10,42 of FIGS. 1 and 3 avoids the cantilevered suspension of the laminated bus bar 14 off the capacitor terminals 20, thus reducing inbuilt stresses on the capacitor terminals 20. In the assembly and disassembly sequences for the power electronic module 42 of FIG. 3, the laminated bus bar 14 is attached to the capacitor unit 12 and IGBTs 16 only after the capacitor unit 12 and IGBTs 16 have been mounted in place on the support rail 18, thus also reducing inbuilt stresses on the junction terminals of the IGBTs 16.

The omission of the bent portion for engagement with the capacitor terminals 20 improves manufacturing accuracy and reduces manufacturing costs, since the terminal tab slots 32 and fastener openings 36 are arranged to be substantially coplanar to allow for a simpler linear tolerance stack.

It is envisaged that, in other embodiments of the invention, the recess is omitted from the side wall such that the outer surface of the side wall is formed as a flat surface.

It is also envisaged that, in still other embodiments of the invention, each capacitor terminal may be mounted on the outer surface of the side wall.

It will be appreciated that the embodiments of FIGS. 1 and 3 are intended as non-limiting examples to demonstrate the working of the invention, and the electrical apparatus of the invention may take another form that includes one or more other electrical components alongside the capacitor unit of the invention.

This written description uses examples to disclose the invention, including the preferred embodiments, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What we claim is:

1. A capacitor unit, for use as a high voltage device, comprising:
a capacitor element;
a housing including a plurality of walls arranged to contain the capacitor element within the housing, the plurality of walls including first and second end walls, the plurality of walls further including a side wall extending between the end walls, the outer surface of the side wall being larger than the outer surface of each end wall; and
at least one capacitor terminal electrically connected to the capacitor element, wherein the or each capacitor terminal is mounted on or extends through the side wall.

2. A capacitor unit according to claim 1 wherein a recess is formed in the side wall, and the or each capacitor terminal is mounted on or extends through a base of the recess.

3. A capacitor unit according to claim 2 wherein the height of the or each capacitor terminal above the base of the recess is equal to, greater than, or less than the depth of the recess.

4. A capacitor unit according to claim 2 wherein the recess is formed as an end recess adjacent to one of the end walls.

5. A capacitor unit according to claim 1 wherein the or each capacitor terminal extends perpendicularly or substantially perpendicularly to the outer surface of the side wall.

6. A capacitor unit according to claim 1 wherein the or each capacitor terminal is positioned adjacent to a wall edge that joins the side wall and one of the end walls.

7. A capacitor unit according to claim 1 wherein the capacitor unit is a high voltage device.

8. A capacitor unit according to claim 1 wherein the capacitor unit is rated for use in a high voltage direct current application or a static VAR compensator application.

9. A capacitor unit according to claim 1 wherein the capacitor unit has a voltage rating of more than 1500 V DC.

10. A capacitor unit according to claim 1 wherein the housing is metallic.

11. A capacitor unit according to claim 1 wherein the housing is hermetically sealed.

12. A capacitor unit according to claim 1 further including a or a respective bushing arranged around the or each capacitor terminal.

13-14. (canceled)

15. An electrical apparatus, for use as a high voltage electrical apparatus, comprising: the capacitor unit of claim 1; and
another electrical component including: a component terminal that electrically and releasably engages with the capacitor terminal; or a plurality of component terminals, each of which electrically and releasably engages with a respective one of the capacitor terminals.

16. An electrical apparatus according to claim 15 wherein the or each component terminal includes a slot in which the corresponding capacitor terminal is releasably engaged.

17. An electrical apparatus according to claim 15 wherein the or each component terminal slidably engages with the corresponding capacitor terminal.

18. An electrical apparatus according to claim 16 wherein the or each capacitor terminal is slidably engaged in the slot of the corresponding component terminal.

19. An electrical apparatus according to claim 17 wherein the capacitor unit and the other electrical component are mounted on a support rail so that: the capacitor unit is slidable along the support rail relative to the other electrical component; and/or the other electrical component is slidable along the support rail relative to the capacitor unit.

20. An electrical apparatus according to claim 15 wherein the other electrical component is positioned to be coplanar or substantially coplanar with the capacitor unit.

21. An electrical apparatus according to claim 15 wherein the other electrical component is or includes a bus bar, optionally a laminated bus bar.

22. An electrical apparatus according to claim 15 wherein the or each component terminal electrically and releasably engages with the or the respective capacitor terminal via mechanical contact.

23. An electrical apparatus according to claim 22 wherein the or each component terminal electrically and releasably engages with the or the respective capacitor terminal solely via mechanical contact.

24. An electrical apparatus according to claim 15 wherein the electrical apparatus is a high voltage electrical apparatus.

25. An electrical apparatus according to claim 15 wherein the electrical apparatus is a voltage source converter.

26. An electrical apparatus according to claim 15 wherein the electrical apparatus is rated for use in a high voltage direct current application or a static VAR compensator application.

27-28. (canceled)
